(19) United States
(12) Patent Application Publication
(10) Pub. No.: US 2014/0253252 A1
(43) Pub. Date: Sep. 11, 2014

(54) OSCILLATOR CIRCUIT

(71) Applicant: NIHON DEMPA KOGYO CO., LTD., Tokyo (JP)

(72) Inventor: MINORU FUKUDA, SAITAMA (JP)

(73) Assignee: NIHON DEMPA KOGYO CO., LTD., Tokyo (JP)

(21) Appl. No.: 14/184,679

(22) Filed: Feb. 19, 2014

(30) Foreign Application Priority Data
Mar. 6, 2013 (JP) 2013-043622

(51) Int. Cl. H03B 5/36

(52) U.S. Cl. CPC H03B 5/362
USPC 331/116 R

(57) ABSTRACT

An oscillator circuit includes a crystal unit, a first variable capacitance element, a transistor, and a first capacitance element. The first variable capacitance element is disposed between a first terminal of the crystal unit and a ground. The transistor has a base connected to a second terminal of the crystal unit. The first capacitance element is disposed between an emitter and a collector of the transistor.

### CROSS REFERENCE TO RELATED APPLICATIONS

This application claims the priority benefit of Japan application serial no. 2013-043622, filed on Mar. 6, 2013. The entirety of the above-mentioned patent application is hereby incorporated by reference herein and made a part of this specification.

### TECHNICAL FIELD

This disclosure relates to an oscillator circuit.

### DESCRIPTION OF THE RELATED ART

Conventionally, there is known an oscillator circuit whose oscillation frequency is adjustable (see, for example, Japanese Unexamined Patent Application Publication No. 2001-237643). FIG. 6 illustrates an exemplary configuration of a conventional oscillator circuit 500. The oscillator circuit 500 includes a crystal unit 201, a variable capacitance element 202, a circuit unit 203, a capacitor 204, a capacitor 206, a capacitor 207, a resistor 208, and an inductor 209.

The crystal unit 201 includes one end that is connected to the variable capacitance element 202 via the inductor 209, the capacitor 206, and the capacitor 207 and the other end that is connected to the circuit unit 203 of an oscillation stage. The variable capacitance element 202 is disposed between: the capacitor 206 and the capacitor 207; and a ground. Connecting the circuit unit 203 to the crystal unit 201 constitutes a Colpitts type oscillator circuit.

The oscillator circuit 500 has an oscillation frequency that is determined based on a capacitance value of the variable capacitance element 202, capacitance values of the capacitor 206 and the capacitor 207, and an inductance value of the inductor 209. Changing the capacitance value of the variable capacitance element 202 by changing a control voltage VC can change the oscillation frequency of the oscillator circuit 500.

FIG. 7 is an exemplary configuration of a conventional oscillator circuit 600. The oscillator circuit 600 includes a variable capacitance element 238 instead of a capacitor 235 in the oscillator circuit 500. In the oscillator circuit 600, an oscillation frequency can be changed according to a voltage applied to the variable capacitance element 238.

Now, a load capacitance CL of the entire oscillator circuit 500 in FIG. 6 can be expressed by the following expression (1). Here, D denotes the capacity of the variable capacitance element 202, Ct denotes the capacity of the capacitor 206, Cta denotes the capacity of the capacitor 207, C1 denotes the capacity of a capacitor 234, and C2 denotes the capacity of the capacitor 235. CLL denotes a value expressing −(1/ω²L1), which is an impedance where the inductance value of the inductor 209 is assumed as L1.

CL=1/[1/D+(Ct+Cta)+1/C1+1/C2]+CLL (1)

In the oscillator circuit 500, for example, adjusting the capacity of the capacitor 206 allows changing the oscillation frequency. However, in the case where the variable capacitance element 202 has a comparatively small capacity, this capacity significantly affects the load capacitance CL of the entire oscillator circuit 500. Accordingly, even if the capacity of the capacitor 206 is adjusted, it is difficult to sufficiently change the oscillation frequency of the oscillator circuit 500.

An increase in the inductance value of the inductor 209 ensures the decreased oscillation frequency of the oscillator circuit 500. However, increasing the inductance value of the inductor 209 arises problems that a large mounting area is required and a frequency variable width is changed.

In the oscillator circuit 600 in FIG. 7, when changing the capacity of the variable capacitance element 238 by changing a voltage applied to the variable capacitance element 238, a negative resistance of the circuit unit 203 becomes small. This causes a problem of small oscillation margin.

A need thus exists for an oscillator circuit which is not susceptible to the drawbacks mentioned above.

### SUMMARY

In a first aspect of this disclosure, there is provided an oscillator circuit that includes a crystal unit, a first variable capacitance element, a transistor, and a first capacitance element. The first variable capacitance element is disposed between a first terminal of the crystal unit and a ground. The transistor has a base connected to a second terminal of the crystal unit. The first capacitance element is disposed between an emitter and a collector of the transistor.

### BRIEF DESCRIPTION OF THE DRAWINGS

The foregoing and additional features and characteristics of this disclosure will become more apparent from the following detailed description considered with reference to the accompanying drawings, wherein:

FIG. 1 illustrates an exemplary configuration of an oscillator circuit according to a first embodiment.

FIG. 2 lists simulation results of a deviation amount of an oscillation frequency of a crystal oscillator.

FIG. 3 illustrates an exemplary configuration of an oscillator circuit according to a second embodiment.

FIG. 4 illustrates an exemplary configuration of an oscillator circuit according to a third embodiment.

FIG. 5 illustrates an exemplary configuration of an oscillator circuit according to a fourth embodiment.

FIG. 6 illustrates an exemplary configuration of a conventional oscillator circuit.

FIG. 7 illustrates an exemplary configuration of a conventional oscillator circuit.

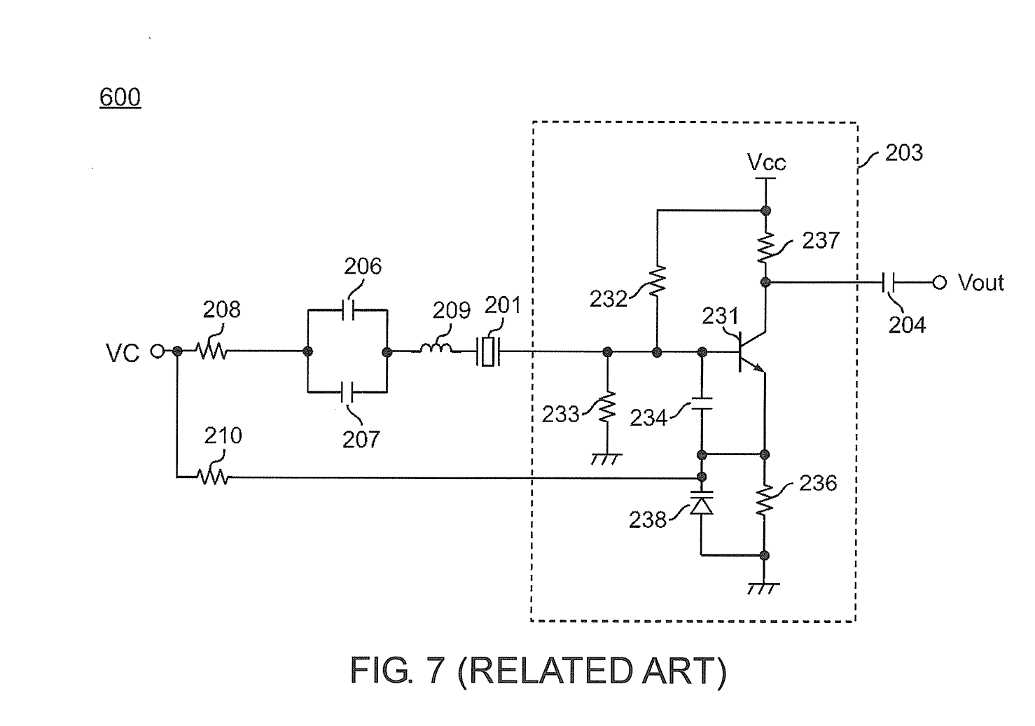

### DETAILED DESCRIPTION

### Circuit Configuration of Oscillator Circuit 100 of First Embodiment

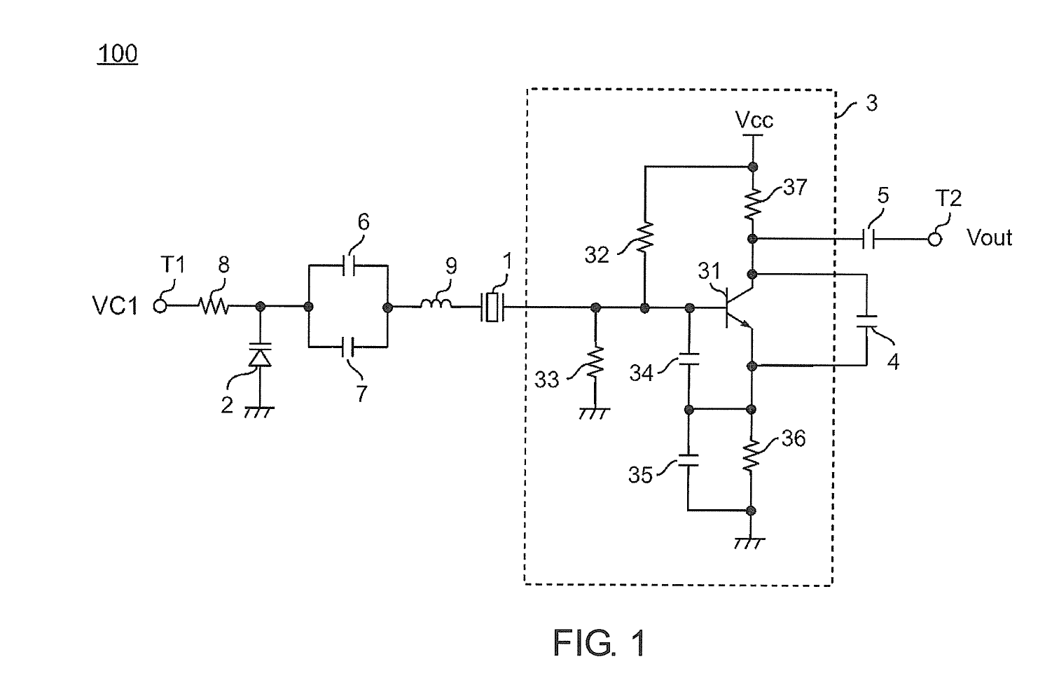

FIG. 1 illustrates an exemplary configuration of the oscillator circuit 100 according to the first embodiment. The oscillator circuit 100 includes a crystal unit 1, a variable capacitance element 2, a circuit unit 3, a capacitor 4, a capacitor 5, a capacitor 6 and a capacitor 7 which are connected in parallel to one another, a resistor 8, and an inductor 9.

The crystal unit 1 is a crystal resonator using, for example, an AT-cut crystal element. The crystal unit 1 includes a first terminal of that is connected to the variable capacitance element 2 via the capacitor 6, the capacitor 7, and the inductor 9. The crystal unit 1 includes a second terminal that is connected to the circuit unit 3.

The variable capacitance element 2 is, for example, a varicap diode. The variable capacitance element 2 is disposed between the first terminal of the crystal unit 1 and a ground. The variable capacitance element 2 changes its impedance according to a control voltage VC1 applied to an input terminal T1. The change in the impedance of the variable capacitance element 2 changes the oscillation frequency of the oscillator circuit 100. Specifically, an increase in the control voltage VC1 decreases the capacity of the variable capacitance element 2, making the oscillation frequency high. A decrease in the control voltage VC1 increases the capacity of the variable capacitance element 2, making the oscillation frequency low.

The circuit unit 3 is a circuit at an oscillation stage forming a Colpitts oscillator circuit by connection with the crystal unit 1. The circuit unit 3 includes a transistor 31, a resistor 32, a resistor 33, a capacitor 34, a capacitor 35, a resistor 36, and a resistor 37.

The transistor 31 is, for example, an NPN-type transistor. A base of the transistor 31 is connected to a second terminal of the crystal unit 1. The base of the transistor 31 is connected to the resistor 32, the resistor 33, and the capacitor 34.

The resistor 32 and the resistor 33 are resistors for determining a bias voltage of the transistor 31. The resistor 32 is disposed between a connection point of the base of the transistor 31 with the crystal unit 1 and a power source Vcc. The resistor 33 is disposed between a connection point of the base of the transistor 31 with the crystal unit 1 and the ground.

Between an emitter of the transistor 31 and a ground, the resistor 36 is disposed. The emitter of the transistor 31 is connected to a connection point of the capacitor 34 with the capacitor 35. The collector of the transistor 31 is connected to the power source Vcc via the resistor 37. The collector of the transistor 31 outputs an oscillation signal to the outside via the capacitor 5 and an output terminal T2.

Between the emitter and the collector of the transistor 31, the capacitor 4 is disposed as the first capacitance element. Disposing the capacitor 4 between the emitter and the collector of the transistor 31 ensures oscillation of the oscillator circuit 100 at a frequency different from an oscillation frequency in the case where the capacitor 4 is not disposed. Specifically, the oscillation frequency of the oscillator circuit 100 is reduced by disposing the capacitor 4. The oscillation frequency is determined according to the capacitance value of the capacitor 4.

### Simulation Result

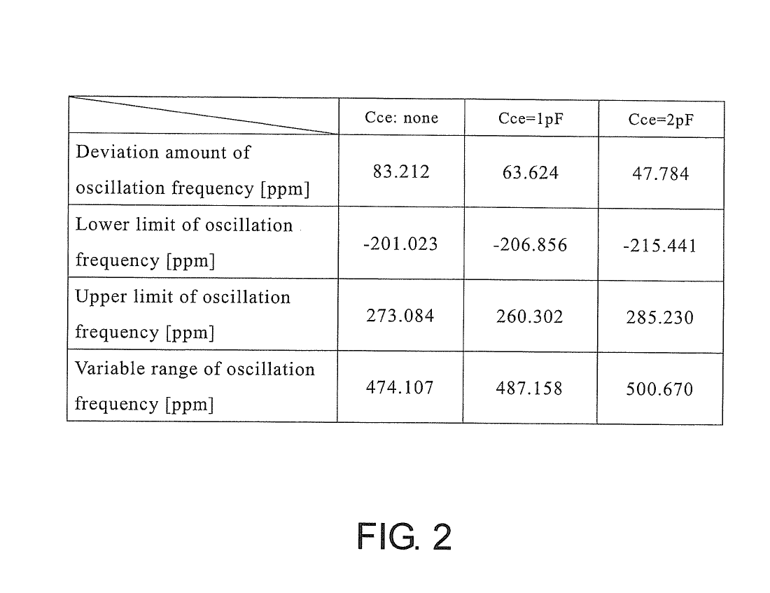

FIG. 2 lists simulation results of a deviation amount of the oscillation frequency and a variable range of the oscillation frequency when the capacitance value of the capacitor 4 of the oscillator circuit 100 is changed. FIG. 2 lists simulation results of the deviation amount of the oscillation frequency of the oscillator circuit 100, the lower limit value of the oscillation frequency, the upper limit value of the oscillation frequency, and the variable range of the oscillation frequency in the cases where: the capacitor 4 is not disposed, a capacitance value Cce of the capacitor 4 is set to 1 pF, and the capacitance value Cce of the capacitor 4 is set to 2 pF, respectively.

Here, the deviation amount of the oscillation frequency is a deviation amount with respect to an oscillation frequency fc of the crystal unit 1 where the control voltage VC1 is a half of the supply voltage Vcc. The lower limit value of the oscillation frequency is a deviation amount with respect to the oscillation frequency fc at the smallest control voltage VC1. The upper limit value of the oscillation frequency is a deviation amount with respect to the oscillation frequency fc at the largest control voltage VC1. The magnitude of the variable range of the oscillation frequency is equal to a frequency difference between the upper limit value of the oscillation frequency and the lower limit value of the oscillation frequency.

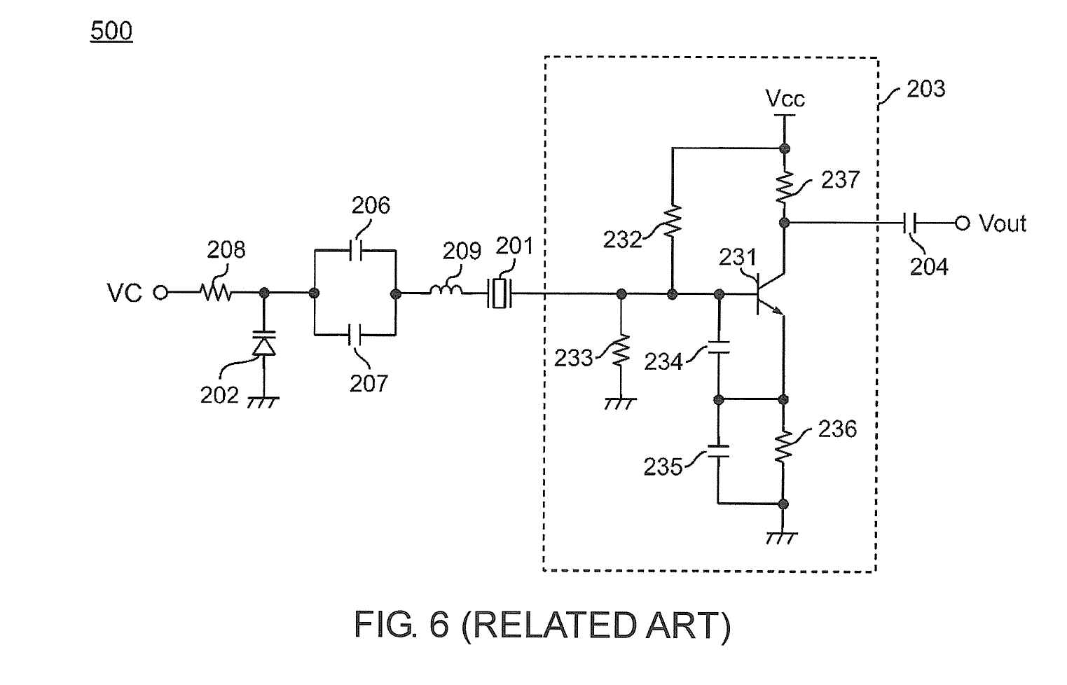

From the deviation amount of the oscillation frequency illustrated in FIG. 2, it can be confirmed that adjusting the capacitance value of the capacitor 4 changes the oscillation frequency. In the oscillator circuit 100, only a change of 1 pF in the capacitance value of the capacitor 4 changes the oscillation frequency approximately 15 ppm to 20 ppm. Compared with the conventional oscillator circuit 500 illustrated in FIG. 6, the oscillation frequency can be changed in a wide range. It is clear from FIG. 2 that a change in the capacitance value of the capacitor 4 does not hardly change the magnitude of the variable range of the oscillation frequency.

As described above, according to the first embodiment, the capacitor 4 is disposed between the emitter and the collector of the transistor 31, which constitutes a Colpitts type oscillator circuit. This ensures effectively changing the oscillation frequency while the magnitude of the variable range of the oscillation frequency is maintained.

### Second Embodiment

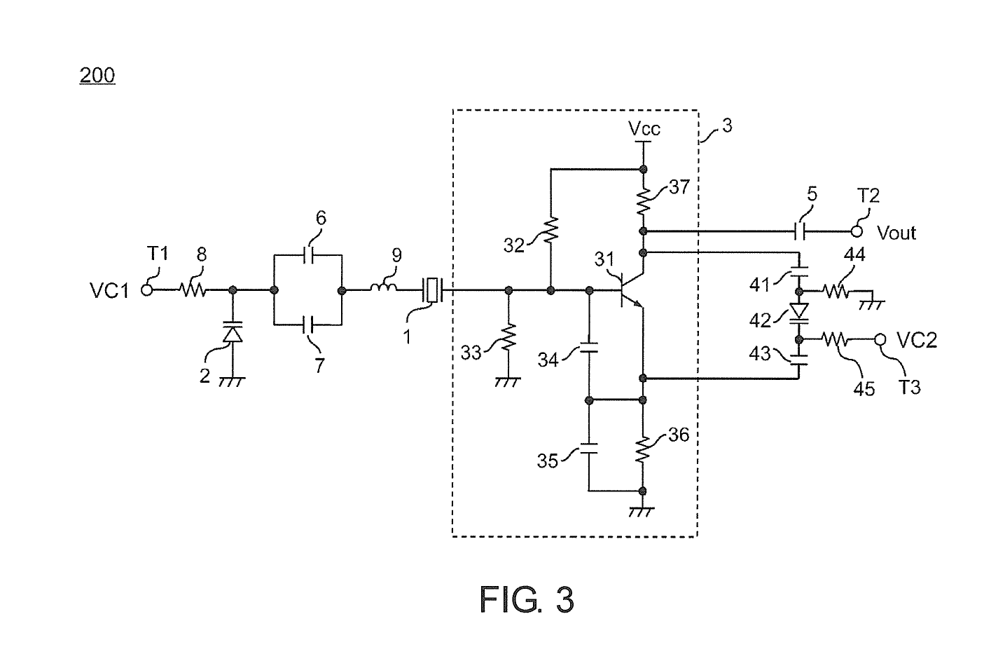

FIG. 3 illustrates an exemplary configuration of an oscillator circuit 200 according to the second embodiment. The oscillator circuit 200 according to the second embodiment differs from the oscillator circuit 100 illustrated in FIG. 1 in that a capacitor 41, a variable capacitance element 42, a capacitor 43, a resistor 44, and a resistor 45 are disposed between the collector and the emitter of the transistor 31. The oscillator circuit 200 is otherwise the same as the oscillator circuit 100.

In the second embodiment, the capacitor 41 includes one end that is connected to the collector of the transistor 31 and the other end that is connected to the variable capacitance element 42. The variable capacitance element 42 includes one end that is connected to the capacitor 41 and the other end that is connected to the capacitor 43. The capacitor 43 includes one end that is connected to the variable capacitance element 42 and the other end that is connected to the emitter of the transistor 31. That is, in the oscillator circuit 200, the capacitor 41, the variable capacitance element 42, and the capacitor 43 are connected in series between the collector and the emitter of the transistor 31.

The resistor 44 is disposed between a connection point of the capacitor 41 and the variable capacitance element 42, and a ground. The resistor 45 is disposed between: a connection point of the capacitor 43 and the variable capacitance element 42; and an input terminal T3 of a control voltage VC2.

The capacitance value of the variable capacitance element 42 changes according to the control voltage VC2. Accordingly, a change in the control voltage VC2 changes a magnitude of a capacity between the collector and the emitter of the transistor 31, allowing changing the oscillation frequency of the oscillator circuit 200. Specifically, an increase in the control voltage VC2 decreases the capacitance value of the variable capacitance element 42, making the oscillation frequency high.

In the oscillator circuit 200, changes in the control voltage VC1 and the control voltage VC2 change capacitance values of the variable capacitance element 2 and the variable capacitance element 42, allowing changing the oscillation frequency in a wider frequency range using the control voltage VC1 and the control voltage VC2. The control voltage VC1 may be input to the input terminal T3.

### Third Embodiment

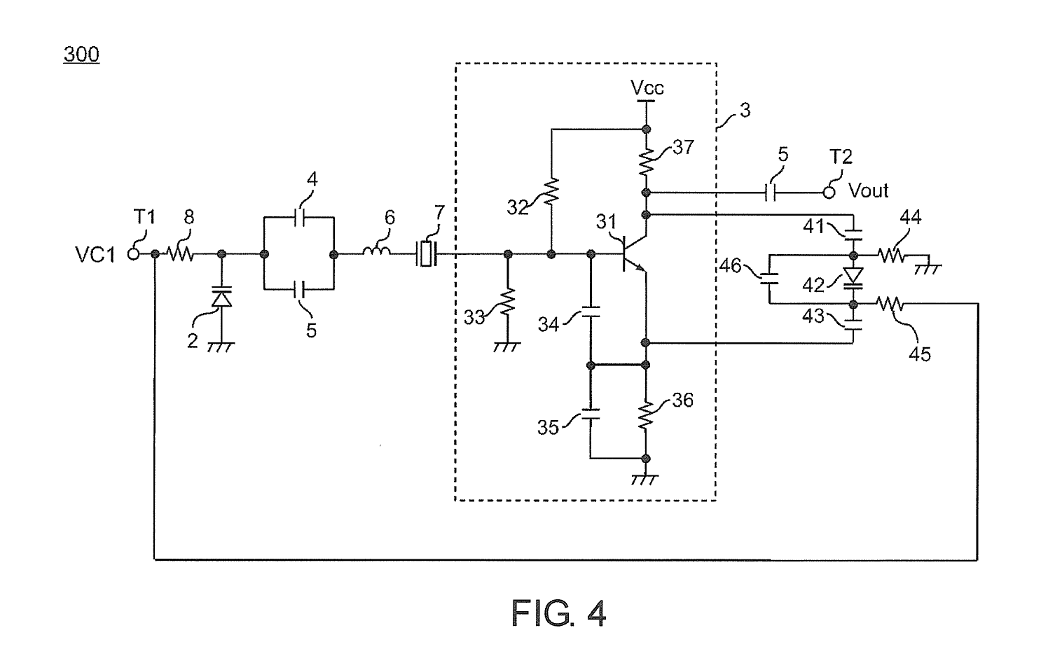

FIG. 4 illustrates an exemplary configuration of an oscillator circuit 300 according to the third embodiment. The oscillator circuit 300 according to the third embodiment differs from the oscillator circuit 200 illustrated in FIG. 3 in that a capacitor 46 is disposed in parallel to the variable capacitance element 42 in the oscillator circuit 200 illustrated in FIG. 3. The control voltage VC1, which is applied to the variable capacitance element 2, is applied to the variable capacitance element 42.

In the oscillator circuit 300, the capacitor 46 and the variable capacitance element 42 are connected in parallel between the collector and the emitter of the transistor 31. Since the capacitor 46 is disposed in parallel to the variable capacitance element 42, an amount of change of the capacitance value between the collector and the emitter of the transistor 31 with respect to an amount of change of the control voltage VC1 decreases. That is, a ratio that a change in the capacitance value of the variable capacitance element 42 contributes to an amount of change of the oscillation frequency when the control voltage VC1 is changed becomes small. Accordingly, in the case where, for example, the oscillator circuit 300 is employed as a voltage controlled oscillator for a PLL circuit, this ensures stable operations without rapidly changing the oscillation frequency due to the change in the capacitance value of the variable capacitance element 42.

### Fourth Embodiment

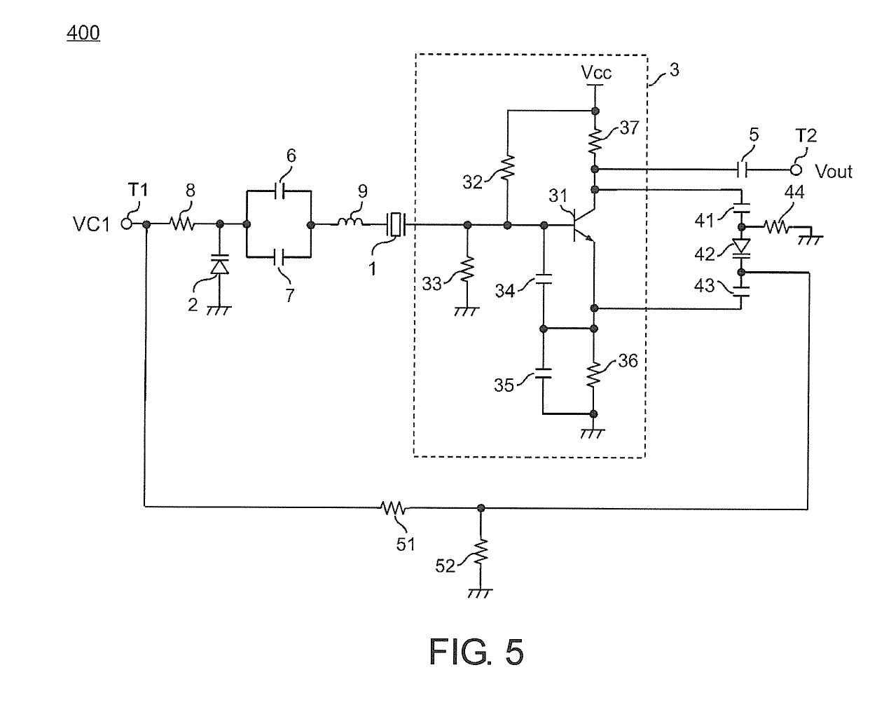

FIG. 5 illustrates an exemplary configuration of an oscillator circuit 400 according to the fourth embodiment. The oscillator circuit 400 according to the fourth embodiment differs from the oscillator circuit 200 illustrated in FIG. 3 in that a voltage dividing unit, which is constituted of a resistor 51 and a resistor 52, is disposed, and a voltage where the control voltage VC1 is divided by the resistor 51 and the resistor 52 is applied to the variable capacitance element 42. The oscillator circuit 400 is otherwise the same as the oscillator circuit 200.

In the oscillator circuit 400, the resistor 51 is disposed between the input terminal T1 and the variable capacitance element 42. The resistor 52 is disposed between: a connection point of the resistor 51 and the variable capacitance element 42; and a ground.

In the oscillator circuit 400, a divided voltage, which is a voltage where the control voltage VC1 input to the variable capacitance element 2 is divided, is applied to the variable capacitance element 42. Accordingly, a ratio of an amount of change of the voltage applied to the variable capacitance element 42 with respect to an amount of change of the control voltage VC1 becomes small compared with the case where the resistor 51 and the resistor 52 are not disposed. Consequently, similarly to the oscillator circuit 300, in the case where the oscillator circuit 400 is employed as a voltage controlled oscillator for a PLL circuit, this ensures stable operations without rapidly changing the oscillation frequency due to a change in the capacitance value of the variable capacitance element 42.

This disclosure is described with the embodiments. The technical scope of this disclosure is not limited to the above-described embodiments. Various modifications and improvements of the embodiments will become apparent to those skilled in the art. In the above-described embodiments, for example, the transistor 31 is a bipolar transistor. However, the transistor 31 may be a field-effect transistor. It is apparent that embodiments thus modified and improved are also within the technical scope of this disclosure according to the description of the claims.

In the oscillator circuit, as the first capacitance element, a second variable capacitance element may be disposed between an emitter and a collector of the transistor. In the oscillator circuit, a second capacitance element may be disposed in parallel to the second variable capacitance element. The oscillator circuit may further include a voltage dividing unit. The voltage dividing unit may be configured to divide a voltage applied to the first variable capacitance element and apply the divided voltage to the second variable capacitance element.

With the oscillator circuit according to the embodiments, it is possible to ensure the effects that can change an oscillation frequency and can maintain a variable frequency width properly.

The principles, preferred embodiment and mode of operation of the present invention have been described in the foregoing specification. However, the invention which is intended to be protected is not to be construed as limited to the particular embodiments disclosed. Further, the embodiments described herein are to be regarded as illustrative rather than restrictive. Variations and changes may be made by others, and equivalents employed, without departing from the spirit of the present invention. Accordingly, it is expressly intended that all such variations, changes and equivalents which fall within the spirit and scope of the present invention as defined in the claims, be embraced thereby.

What is claimed is:

1. An oscillator circuit, comprising:
a crystal unit;
a first variable capacitance element, disposed between a first terminal of the crystal unit and a ground;
a transistor, having a base connected to a second terminal of the crystal unit; and
a first capacitance element, disposed between an emitter and a collector of the transistor.

2. The oscillator circuit according to claim 1, wherein
the first capacitance element includes a second variable capacitance element disposed between the emitter and the collector of the transistor.

3. The oscillator circuit according to claim 2, further comprising:
a second capacitance element, disposed in parallel to the second variable capacitance element.

4. The oscillator circuit according to claim 2, further comprising:
a voltage dividing unit, configured to divide a voltage applied to the first variable capacitance element and apply the divided voltage to the second variable capacitance element.

5. The oscillator circuit according to claim 3, further comprising:
a voltage dividing unit, configured to divide a voltage applied to the first variable capacitance element and apply the divided voltage to the second variable capacitance element.
